(19) United States
(12) Patent Application Publication
(10) Pub. No.: US 2014/0291630 A1
(43) Pub. Date: Oct. 2, 2014

(54) ORGANIC LIGHT-EMITTING DIODE DISPLAY AND METHOD OF MANUFACTURING SAME

(71) Applicant: Samsung Display Co., Ltd., Yongin-City (KR)

(72) Inventor: Jun Namkung, Yongin-City (KR)

(73) Assignee: Samsung Display Co., Ltd., Yongin-City (KR)

(21) Appl. No.: 14/012,967

(22) Filed: Aug. 28, 2013

(30) Foreign Application Priority Data
Apr. 1, 2013 (KR) 10-2013-0035458

(51) Int. Cl. H01L 27/32; H01L 51/56

(52) U.S. Cl. CPC H01L 27/3244; H01L 51/56
USPC 257/40; 438/23

(57) ABSTRACT

Provided is an organic light-emitting diode (OLED) display including a flexible substrate; a driving circuit unit on the flexible substrate and having a thin film transistor (TFT); an OLED on the flexible substrate and coupled to the driving circuit unit; a sealing layer on the flexible substrate at the OLED and the driving circuit unit; and a first protective film on the flexible substrate, wherein the first protective film includes a photoresist material.

### CROSS-REFERENCE TO RELATED APPLICATION

This application claims priority to and the benefit of Korean Patent Application No. 10-2013-0035458, filed on Apr. 1, 2013, in the Korean Intellectual Property Office, the disclosure of which is incorporated herein in its entirety by reference.

### BACKGROUND

1. Field

Aspects of present invention relate to an organic light-emitting diode display and a method of manufacturing the same.

2. Description of the Related Art

An organic light-emitting diode (OLED) display includes a hole injection electrode, an electron injection electrode, and an organic light-emitting layer therebetween, and is a self-emitting display that emits light while holes injected from an anode and electrons injected from a cathode recombine and disappear at/from an organic light-emitting layer.

In addition, because the OLED display has good characteristics, such as low power consumption, high luminescence, and fast response speeds, it has received attention as a next-generation display of portable electronic equipment.

However, if a heavy, fragile glass substrate is used in the OLED display, it has limitations in portability and displaying by a large screen.

Thus, a flexible OLED display is being developed by using a flexible substrate, such as a plastic substrate. Accordingly, a surface of the flexible substrate, such as the plastic substrate, and the inside of a panel need to be protected.

### SUMMARY

Embodiments of the present invention provide an organic light-emitting diode (OLED) display with relatively enhanced durability and that has a thickness that may be relatively easily adjusted.

Embodiments of the present invention also provide a method of manufacturing the OLED display.

According to an embodiment of the present invention, there is provided an organic light-emitting diode (OLED) display, including a flexible substrate; a driving circuit unit on the flexible substrate and including a thin film transistor (TFT); an OLED on the flexible substrate and coupled to the driving circuit unit; a sealing layer on the flexible substrate and covering the OLED and the driving circuit unit; and a first protective film on the flexible substrate, wherein the first protective film includes a photoresist material.

The first protective film may include an epoxy based negative tone photoresist material.

The first protective film may have a thickness of 10 μm to 100 μm.

The flexible substrate may be made of a plastic material.

The sealing layer may include one or more organic layers and one or more inorganic layers that are alternately stacked.

The OLED display may further include a barrier film directly on the flexible substrate.

The OLED display may further include a second protective film directly on the flexible substrate, wherein the second protective film includes a photoresist material.

The second protective film may include an epoxy based negative tone photoresist material.

The second protective film may have a thickness of 10 μm to 100 μm.

The OLED display may further include a barrier film directly on the second protective film.

According to another aspect of the present invention, there is provided a method of manufacturing an OLED display, the method including positioning a flexible substrate on a glass substrate; forming, on the flexible substrate, a driving circuit unit including a thin film transistor (TFT), and an OLED coupled to the driving circuit unit; forming, on the flexible substrate, a sealing layer on the OLED and the driving circuit unit; separating the glass substrate from the flexible substrate; and forming, on the flexible substrate, a first protective film including a photoresist material.

The first protective film may include an epoxy based negative tone photoresist material.

The first protective film may be formed by a spin coating technique.

In the spin coating technique, a thickness of the first protective film may be adjusted according to a spin speed of the flexible substrate.

The first protective film may be formed by a slit coating technique.

By the slit coating technique, a width of a slit nozzle may be 650 mm to 750 mm, and a speed of the slit nozzle may be 10 m/s to 20 m/s.

The first protective film may have a thickness of 10 μm to 100 μm.

The method may further include forming a barrier film directly on the flexible substrate after positioning the flexible substrate on the glass substrate.

The flexible substrate may include a plastic material.

The sealing layer may include one or more organic layers and one or more inorganic layers that are alternately stacked.

### BRIEF DESCRIPTION OF THE DRAWINGS

The above and other features and aspects of the embodiments of the present invention will become more apparent by describing in some detail embodiments thereof with reference to the attached drawings in which:

FIG. 1 is a sectional view of an OLED display according to an embodiment of the present invention;

FIG. 2 is a sectional view of an OLED display according to another embodiment of the present invention;

FIG. 3 is a sectional view of an OLED display according to another embodiment of the present invention;

FIGS. 4A to 4C are sectional views of some of the process steps for manufacturing the OLED display of FIG. 1;

FIGS. 5 and 6 are perspective views of some of the process steps for manufacturing the OLED display of FIG. 1;

FIG. 7 is a circuit diagram of a pixel circuit of a pixel of a display panel of the OLED of FIG. 1;

FIG. 8 is an expanded view of an internal structure of a display panel of the OLED display of FIG. 1;

FIG. 9 is a sectional view taken along the line VI-VI of FIG. 8; and

FIG. 10 is a graph illustrating a relationship between spin speed and protective film materials and thicknesses.

### DETAILED DESCRIPTION

Because embodiments of the present invention make various modifications and there are several embodiments, particular embodiments will be illustrated in the drawings and described in the detailed description in more detail. However, it is not intended to limit the present invention to particular embodiments but it should be understood that the present invention covers all modifications, equivalents, and replacements that fall within the scope and technology of the present invention. Detailed descriptions related to well-known functions or configurations will be ruled out if it is determined that they may make subject matters of the present invention unnecessarily obscure in describing the present invention.

It will be understood that although the terms ‘first’ and ‘second’ are used herein to describe various elements, these elements should not be limited by these terms. The terms are used only in order to distinguish a component from another component.

The terms used herein are just to describe particular embodiments and not intended to limit the present invention. The terms of a singular form may include plural forms unless referred to the contrary. The terms “include”, “comprise”, or “has” specifies that there is a property, a number, a step, an operation, a component, a part, or its combinations in the specification but do not exclude other properties, numbers, steps, operations, components, parts, or their combinations.

In addition, the size and thickness of each component in the drawings are examples, and are not limited thereto.

The thicknesses of several layers and regions have been expanded in the drawings for clarity of the several layers and regions. In the drawings, the thicknesses of some layers and regions have been exaggerated for convenience of description. it will be understood that when an element such as a layer, film, region, or substrate is referred to as being “on” another element, it can be directly on the other element or intervening elements may also be present.

Embodiments of the present invention will be described in more detail with reference to the accompanying drawings.

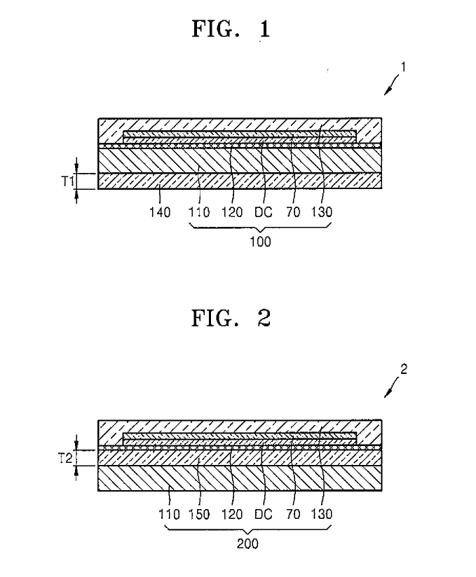

An embodiment of the present invention is described with reference FIG. 1.

As shown in FIG. 1, an organic light-emitting diode (OLED) display 1 according to an embodiment of the present invention includes a display panel 100 and a first protective film 140.

The display panel 100 includes a flexible substrate 110, a driving circuit unit DC, an OLED 70, and a sealing layer 130.

The flexible substrate 110 is formed of a flexible plastic material. However, the embodiment of the present invention is not limited thereto, and the flexible substrate 110 may be a metal substrate that is formed of stainless steel. In addition, other various flexible materials may be used for the flexible substrate 110.

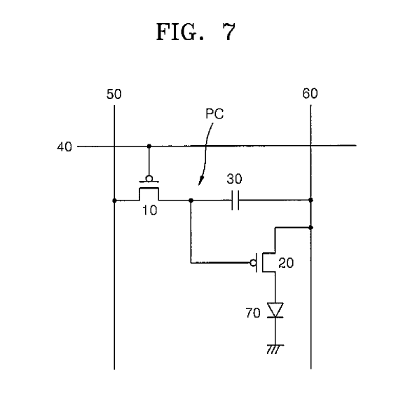

The driving circuit unit DC includes thin film transistors 10 and 20 (shown in FIG. 7) and drives the OLED 70. The OLED 70 is coupled to the driving circuit unit DC and emits light in response to a driving signal transferred from the driving circuit unit DC to display an image.

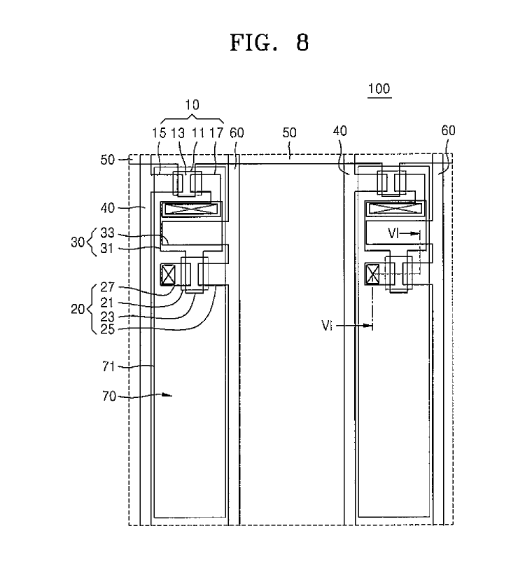

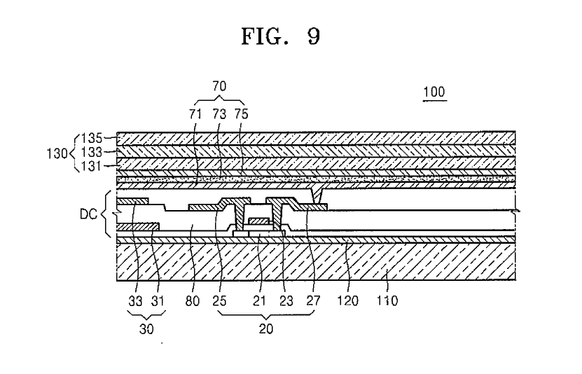

Although some of the detailed structures of the OLED 70 and driving circuit unit DC are shown, embodiments of the present invention are not limited to the structures that are shown in FIGS. 8 and 9. The OLED 70 and driving circuit unit DC may be formed in various suitable structures that may be varied by one of ordinary skill in the art.

In one embodiment, the sealing layer 130 is formed in a multi-layer structure. The sealing layer 130 may be formed as a plurality of inorganic films or by mixing an inorganic film with an organic film. In an embodiment of the present invention, the sealing layer 130 may be formed by using various kinds of inorganic films and organic films that are known to one of ordinary skill in the art.

In addition, the display panel 100 further includes a barrier film 120 between the flexible substrate 110 and the driving circuit unit DC. The barrier film 120 may be formed as one or more of various inorganic and organic films. The barrier film 120 prevents an undesired element, such as moisture, from penetrating into the flexible substrate 110 and permeating into the OLED 70. The moisture permeating into the OLED 70 reduces the life of the OLED 70.

The first protective film 140 is arranged to face the flexible substrate 110.

The first protective film 140 plays a role of enhancing the mechanical strength of the display panel 100. The first protective film 140 may be formed of a photoresist material. Because the first protective film 140 that has been formed of the photoresist material is arranged to face the flexible substrate 110, it is possible to protect the display panel 100 against physical force in processes. In an embodiment of the present invention, various kinds of photoresist materials that are known to one of ordinary skill in the art may be used for the first protective film 140.

As an example material for the first protective film 140, epoxy-based negative tone photoresist may be used. The epoxy material is one of the thermosetting plastics that is resistant to a change of environment, and may thus protect the display panel 100.

As an example material for the first protective film 140, KMPR manufactured by MicroChem Co. and SU-8 manufactured by the same company may be used. Because the KMPR or the SU-8 is used as a material for the first protective film 140, it is possible to easily adjust a thickness T1 of the first protective film 140 in order to match the characteristics of finished goods.

In addition, the first protective film 140 may have a thickness of (i.e., in a range of) 10 μm to 100 μm. If the thickness T1 of the first protective film 140 is formed less than 10 μm, a function as a panel protecting film may not be satisfied in manufacturing processes in view of physical properties, such as the hardness or modulus of elasticity of an epoxy-based resin. On the contrary, if the thickness T1 of the first protective film 140 is formed greater than 100 μm, the total thickness of the OLED display 1 may become unnecessarily thicker. In addition, the flexible property of the OLED display 1 according to an embodiment of the present invention may be degraded.

FIG. 2 is a sectional view of an OLED display 2 according to another embodiment of the present invention.

This embodiment is described in terms of some of its difference from the embodiment of FIG. 1 described previously. In this case, the same reference numerals as those shown in FIG. 1 indicate the same or similar members that perform the same or similar functions.

Referring to FIG. 2, the OLED display 1 according to an embodiment of the present invention includes a display panel 200.

The display panel 200 includes the flexible substrate 110, the driving circuit unit DC, the OLED 70, the sealing layer 130, and a second protective film 150.

The second protective film 150 is formed directly on the flexible substrate 110. The second protective film 150 plays a role of enhancing the mechanical strength of the display panel 200. The first protective film 150 may be formed of a photoresist material. Because the second protective film 150 that has been formed of the photoresist material is arranged directly on the display panel 200, it is possible to protect, against physical force, the driving circuit unit DC and the OLED 70 in the display panel 200. In this embodiment, various suitable kinds of photoresist materials that are known to one of ordinary skill in the art may be used for the second protective film 150.

As an example material for the second protective film 150, epoxy-based negative tone photoresist may be used. The epoxy material is one of the thermosetting plastics that is resistant to a change of environment, and may thus effectively protect the driving circuit unit DC and the OLED 70 in the display panel 200.

As an example material for second protective film 150, KMPR manufactured by MicroChem Co. and SU-8 manufactured by the same company may be used.

Because the KMPR or the SU-8 are used as a material for the second protective film 150, it is possible to easily adjust a thickness T2 of the second protective film 150 in order to match the property of finished goods.

In addition, the thickness T2 of the second protective film 150 may be in a range of 10 μm to 100 μm. If the thickness T2 of the second protective film 150 is formed less than 10 μm, a function as a panel protecting film may not be satisfied in manufacturing processes in view of physical properties such as the hardness or modulus of elasticity of an epoxy-based resin. On the contrary, if the thickness T2 of the second protective film 150 is formed greater than 100 μm, the total thickness of the OLED display 2 may become unnecessarily thicker. In addition, when the thickness T2 of the second protective film 150 is greater than 100 μm, the flexible property of the OLED display 2 according to an embodiment of the present invention may be degraded.

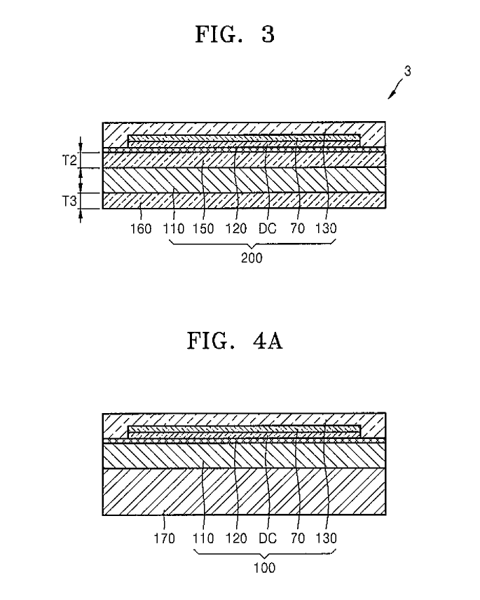

FIG. 3 is a sectional view of an OLED display 3 according to another embodiment of the present invention.

Referring to FIG. 3, the OLED display 3 according to an embodiment of the present invention includes the display panel 200 and the third protective film 160.

The display panel 200 includes the flexible substrate 110, a driving circuit unit DC, the OLED 70, the sealing layer 130, and the second protective film 150.

The third protective film 160 is arranged on a surface of the flexible substrate 110 opposite the second protective film 150. The third protective film 160 plays a role of enhancing the mechanical strength of the display panel 200.

The second and third protective films 150 and 160 may be formed of a photoresist material. Because the third protective film 160 that has been formed of the photoresist material is arranged on the flexible substrate 110, it is possible to protect the display panel 200 against damage caused by physical force during processing of the display panel 200. In addition, because the second protective film 150 that has been formed of the photoresist material is arranged directly on the flexible substrate 110, it is possible to protect or substantially protect, against physical force, the driving circuit unit DC and the OLED 70 in the display panel 200 in processes. As a result, because the driving circuit unit DC and the OLED 70 are doubly protected by the second and third protective films 150 and 160, it is possible to enhance the mechanical reliability of the OLED display 3. In this embodiment, various kinds of photoresist materials that are known to one of ordinary skill in the art may be used for the second and third protective films 150 and 160.

As an example material for the second and third protective films 150 and 160, epoxy-based negative tone photoresist may be used. The epoxy material is one of the thermosetting plastics that is resistant to a change of environment, and may thus effectively protect the display panel 200, the driving circuit unit DC and OLED 70 in the display panel 200.

As an example material for the second and third protective films 150 and 160, KMPR manufactured by MicroChem Co. and SU-8 manufactured by the same company may be used. Because the KMPR or the SU-8 are used as a material for the second and third protective films 150 and 160, it is possible to relatively easily adjust the thickness T2 of the second protective film 150 and the thickness T3 of the third protective film 160 in order to match the property of finished goods.

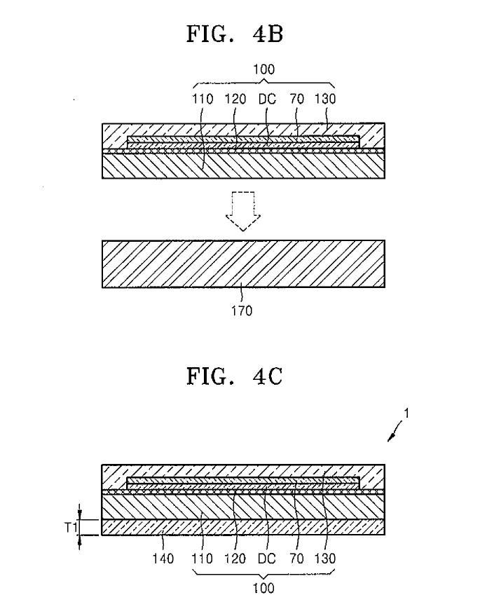

A method of manufacturing the OLED display 1 of FIG. 1 is now described with reference to FIGS. 4A to 4C.

As shown in FIG. 4A, the flexible substrate 110 is positioned on a glass substrate 170. The flexible substrate 110 is formed of a plastic material with a relatively high heat resistance and durability, such as polyethylene ether phthalate, polyethylene naphthalate, polycarbonate, polyarylate, polyetherimide, polyethersulfone, and polyimide.

The flexible substrate 110 that has been formed of the plastic material is bent or stretched if heat is applied thereto, and it is thus difficult to precisely form a thin film pattern having various electrodes or a conductive wiring thereon. Accordingly, while the flexible substrate 110 is adhered to the glass substrate 170, the process of forming several thin film patterns is performed.

Next, the barrier film 120 is formed on the flexible substrate 110, and the driving circuit unit DC and the OLED 70 are formed on the barrier film 120. Then, the sealing layer 130 that covers the OLED 70 and the driving circuit unit DC is formed on the flexible substrate 110 to finish the display panel 100. Alternatively, if the second protective film 150 is formed directly on the flexible substrate 110 prior to forming the barrier film 120 on the flexible substrate 110, it is possible to finish the manufacture of the display panel 200 of FIGS. 2 and 3.

Next, as shown in FIG. 4B, the glass substrate 170 is separated from the flexible substrate 110.

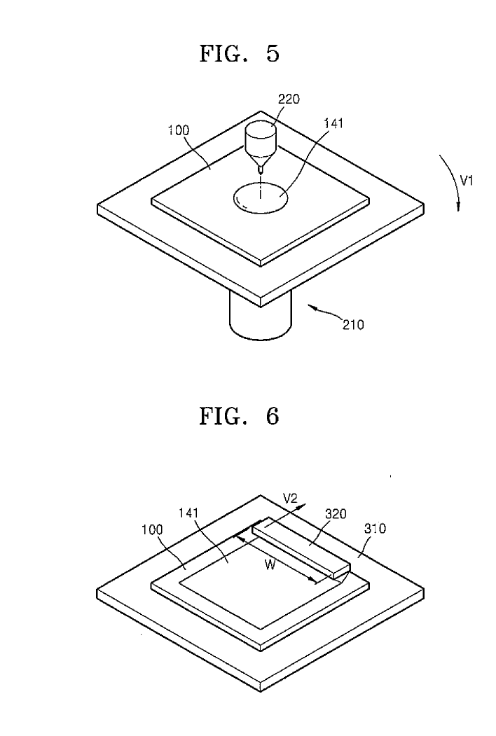

Next, as shown in FIG. 4C, the first protective film 140 is formed on a surface of the flexible substrate 110 from which the glass substrate 170 has been separated. A more detailed description of how the first protective film 140 is formed is made with reference to FIGS. 5 and 6.

In this manufacturing method, it is possible to manufacture the OLED display 1 that has enhanced durability and is slim.

FIGS. 5 and 6 are perspective views of some of the processing steps for manufacturing the OLED display 1 of FIG. 1.

Referring to FIG. 5, the first protective film 140 may be formed by a spin coating technique. A spin coating device includes a stage 210 on which the display panel 100 is mounted, and a dispenser 220 that drops or deposits a coating agent 141 on the display panel 100 as a material for the first protective film 140. In order to coat the coating agent 141, such a spin coating device drops or deposits the coating agent 141 on the display panel 100 and then rotates the display panel 100, or drops or deposits the coating agent 141 and concurrently (e.g., simultaneously) rotates the display panel 100. The coating agent 141 on the display panel 100 is gradually spread according to the rotation of the display panel 100 and the first protective film 140 is thus formed on the display panel 100.

Because the coating agent 141 on the display panel 100 is gradually spread according to the rotation of the display panel 100 and the first protective film 140 is thus formed on the display panel 100, it is possible to adjust the thickness T1 (See FIG. 1) of the first protective film 140 according to the spin speed V1 of the flexible substrate 110.

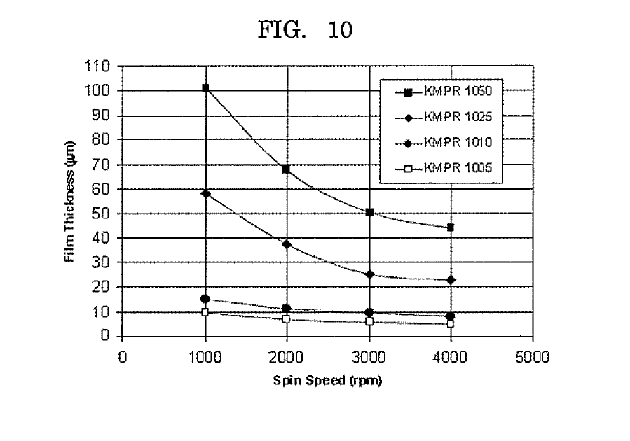

With reference to the graph of FIG. 10 above, a relation between a spin speed V1 and the thickness T1 of the first protective film (i.e., Film Thickness in FIG. 10) depends on the kind or type of protective film material (e.g., KMPR) used when forming the first protective film 140 with a protective film material (e.g., KMPR) using the spin coating technique.

For example, KMPR1005 contains solids in a percentage of 45% and has a viscosity of 95 cSt. In other examples, KMPR1010 contains solids in a percentage of 55% and has a viscosity of 600 cSt, and KMPR1025 contains solids in a percentage of 63.8% and has a viscosity of 4800 cSt. In another example, KMPR1050 contains solids in a percentage of 67.3% and has a viscosity of 13000 cSt.

Referring to the graph of FIG. 10, as the spin speed V1 increases, depending on the type or kind of protective film material (e.g., KMPR), the thickness T1 of the first protective film (i.e., Film Thickness in FIG. 10) decreases. In addition, if the spin speed V1 is the same, the thickness of the first protective film decreases in the order of KMPR1050, KMPR1025, KMPR1010, and KMPR1005.

Thus, it may be seen that when the same spin speed V1 of 1000 rpm is applied, it is possible to adjust the thickness of the protective film from 10 μm to 100 μm depending on the type or kind of protective film material used (such as KMPR). As a result, it is possible to relatively easily adjust the thickness T1 of the first protective film by forming the first protective film 140 using a protective film material such as the KMPR material by the spin coating technique. The relationship between the viscosity and the spin speed may also be applied to other photoresists or poly-based products that have similar or suitable viscosity.

Referring to FIG. 6, the first protective film 140 may alternatively be formed by a slit coating technique. A slit coating device includes a stage 310 on which the display panel 100 is mounted, and a slit nozzle 320. The slit coating device coats the coating agent 141 on the display panel 100 while moving the slit nozzle 320 at a speed (e.g., a given speed) V2 in one direction.

The width W of the slit nozzle may be in a range of 650 mm to 750 mm. if the width W of the slit nozzle 320 is smaller than 650 mm, the width W of the slit nozzle 320 may become smaller than the width of the display panel 100 and it is thus relatively difficult to form the first protective film 140 by performing slit-coating once. If the width W of the slit nozzle 320 is larger than 750 mm, the width W of the slit nozzle 320 may become relatively larger than the width of the display panel 100 and thus may cause inefficiencies with respect to the amount of protective film material that is deposited.

The speed V2 of the slit nozzle 320 may be in a range of 10 m/s to 20 m/s. If the speed V2 of the slit nozzle 320 is slower than 10 m/s, it may increase a manufacturing time for the display panel. If the speed V2 of the slit nozzle 320 is faster than 20 m/s, a problem with uniformity in thickness of a coated protective film may occur. The speed V2 of the slit nozzle, however, may vary according to the viscosity of a protective film material that is used.

Thus, it is possible to adjust the thickness of the first protective film 140 according to the kind or type of protective film (e.g., KMPR), the width W of the slit nozzle 320, and the speed V2 of the slit nozzle 320. As a result, it is possible to relatively easily adjust the thickness T1 of the first protective film by forming the first protective film 140 with the protective film material (e.g., KMPR) by using the slit coating technique. The slit coating technique may also be applied to other photoresists or poly-based products.

With reference to FIGS. 7 to 9, an internal structure of the display panel 100 of the OLED display 1 is described below in more detail. FIG. 7 is a circuit diagram of a pixel circuit PC of a pixel of the display panel 100, FIG. 8 is a diagram of the pixel structure of the display panel 100, and FIG. 9 is a sectional view of the display panel 100 taken along the line VI-VI of FIG. 8.

Referring to FIG. 7, the OLED display 1 according an embodiment of the present invention is coupled to a plurality of signal lines and includes a plurality of pixels that are approximately arranged in the form of a matrix, each pixel having a pixel circuit PC. The pixel is a basic unit that displays an image, and the display panel 100 displays an image through the plurality of pixels.

Each pixel includes a data line 50, a gate line 40, and a common power supply line 60 that is a power supply to drive the OLED 70. The pixel circuit PC is electrically coupled to the data line 50, the gate line 40, and the common power supply line 60, and controls the emitting of light by the OLED 70.

Each pixel includes at least two thin film transistors (TFTs) that are a switching thin film transistor (TFT) 10 and a driving TFT 20, a capacitor 30, and the OLED 70.

The switching TFT 10 is turned on/off by a gate signal applied to the gate line 40, and transfers a data signal applied to the data line 50 to the capacitor 30 and the driving TFT 20. A switching element is not limited only to the switching TFT 10 and it may include a switching circuit that includes a plurality of TFTs and capacitors. In addition, the switching element may further include a circuit that compensates for the value Vth (threshold voltage) of the driving TFT 20, or a circuit that compensates for the voltage drop of the common power supply line 60.

The driving TFT 20 determines an amount of current to flow into the OLED 70 according to the data signal that is transferred through the switching TFT 10.

The capacitor 30 stores the data signal transferred through the switching TFT 10 for a frame.

Although the driving TFT 20 and the switching TFT 10 are represented by PMOS TFTs, the present invention is not limited thereto and at least one of the driving TFT 20 and the switching TFT 10 may, of course, also be an NMOS TFT. In addition, the number of TFTs and capacitors are not limited to the numbers shown, and more TFTs and capacitors may further be included.

As shown in FIGS. 8 and 9, the display panel 100 includes the switching TFT 10, the driving TFT 20, the capacitor 30, and the OLED 70 that are formed for every pixel. In this case, a configuration that includes the switching TFT 10, the driving TFT 20, and the capacitor 30 is referred to as the driving circuit unit DC. In addition, the display panel 100 further includes the gate line 40 arranged in one direction, the data line 50 dielectric-intersecting with the gate line 40, and the common power supply line 60. In this case, one pixel may be defined by, but not be limited to, the gate line 40, the data line 50, and the common power supply line 60.

Although the OLED display 1 of FIG. 8 is an active matrix OLED display having a 2 Tr-1 Cap structure including two TFTs and one capacitor in one pixel, the embodiment of the present invention is not limited thereto. Thus, the OLED display 1 may have three or more TFTs and two or more capacitors in one pixel, and separate wirings may further be formed to have various structures.

The OLED 70 includes a pixel electrode 71, an organic emission layer 73 that is formed on the pixel electrode 71, and a common electrode 75 that is formed on the organic emission layer 73. In this case, the pixel electrode 71 is a hole injection electrode and a positive (+) electrode, and the common electrode 73 is an electron injection electrode and a negative (−) electrode. However, the embodiment of the present invention is not limited thereto, and according to the driving type of the OLED display 1, the pixel electrode 71 may be a negative electrode and the common electrode 75 may be a positive electrode. Holes and electrons respectively from the pixel electrode 71 and the common electrode 75 are injected into the organic emission layer 73. Light is emitted when excitons that are formed by combining the injected holes and electrons drop from an excited state to a ground state.

The organic emission layer 73 may be formed in an opening, and a separate light-emitting material may be formed therein for each pixel. However, the embodiment of the present invention is not limited thereto, and the organic emission layer 73 may be formed in common for all pixels regardless of the location of a pixel. In this case, the organic emission layer 73 may be formed in such a manner that layers including light-emitting materials that emit, e.g., red, green, and blue light, are vertically stacked or combined. In one embodiment, the organic emission layer 73 emits white light or another combination of colors. Another embodiment includes a color conversion layer that converts the emitted white color to another color (e.g., a given color). Another embodiment includes a color filter to filter light emitted from the organic emission layer 73.

In addition, the OLED 70 emits light toward the sealing layer 130 in the OLED display 1 according to an embodiment of the present invention. That is, the OLED 70 is of a top emission type. In this case, in order for the OLED 70 to emit light toward the sealing layer 130, a reflective electrode is used as the pixel electrode 71 and a transmissive or semi-transmissive electrode is used as the common electrode 75. However, in the embodiment of the present invention, the OLED display 1 is not limited to being a top emission type display, and the OLED display 1 may be a bottom emission type display or a dual emission type display.

The capacitor 30 includes a pair of capacitor plates 31 and 33 between which an interlayer insulating film 80 is arranged. In this case, the interlayer insulating film 80 is a dielectric. Capacitance is determined by charges stored in the capacitor 30 and the voltage between both of the capacitor plates 31 and 33.

The switching TFT 10 includes a switching semiconductor layer 11, a switching gate electrode 13, a switching source electrode 15, and a switching drain electrode 17. The driving TFT 20 includes a driving semiconductor layer 21, a driving gate electrode 23, a driving source electrode 25, and a driving drain electrode 27.

In addition, although FIG. 9 shows a TFT having a top gate structure, the embodiment of the present invention is not limited thereto. Thus, a TFT having a bottom gate structure may also be used. In addition, the switching semiconductor layer 11 and the driving semiconductor layer 21 may be formed of poly-crystal silicon but they are not limited thereto and they may be formed of oxide semiconductor. For example, the oxide semiconductor may include oxide of a material that is selected from a metallic element of group 12, 13, and 14, such as Zn, In, Ga, Sn, Cd, Ge, or Hf, and their combinations. For example, the driving semiconductor layer 21 may include G—I—Z—O[(In₂O₃)a(Ga2O3)b(ZnO)c] (where a, b, and c are real numbers and a≧0, b≧0, c≦0).

The switching TFT 10 is used as a switching element to select a pixel from which light is emitted. The switching gate electrode 13 is coupled to the gate line 40.

The switching source electrode 15 is coupled to the data line 50. The switching drain electrode 17 is spaced from the switching source electrode 15 and coupled to the capacitor plate 31.

The driving TFT 20 supplies power to the pixel electrode 71 so that the organic emission layer 73 of the OLED 70 in a selected pixel emits light. The driving gate electrode 23 is coupled to the capacitor plate 31 that is coupled to the switching drain electrode 17. The driving source electrode 25 and the other capacitor plate 33 are coupled to the common power supply line 60. The driving drain electrode 27 is coupled to the pixel electrode 71 of the OLED 70 through a contact hole.

By this structure, the switching TFT 10 is operated by applying a gate voltage to the gate line 40 for transferring, to the driving TFT 20, a data voltage applied to the data line 50. A voltage that corresponds to the difference between the common voltage applied from the common power supply line 60 to the driving TFT 20 and the data voltage transferred from the switching TFT 10 is stored in the capacitor 30, and a current that corresponds to the voltage stored in the capacitor 30 flows to the OLED 70 through the driving TFT 20 to make the OLED 70 emit light.

As shown in FIG. 9, the sealing layer 130 is arranged on the OLED 70 to protect the OLED 70 and the driving circuit unit DC. The sealing layer 130 may be formed in such a manner that one or more organic layers 133 and one or more inorganic layers 131 and 135 are alternately stacked. There may be two or more inorganic layers or two or more organic layers. An organic layer is formed of polymer and may be a stacked film or a single layer that is formed of any of polyethylene terephthalate, polyimide, polycarbonate, epoxy, polyethylene, and polyacrylate. The organic emission layer 73 may be formed of polyacrylate, and in in one embodiment, includes a material obtained through polymerization of monomer composite that includes diacrylate-based monomer and triacrylate-based monomer. The monomer composite may further include monoacrylate-based monomer. In addition, the monomer composite may further include, but is not limited to, a suitable photoinitiator such as TPO.

An inorganic layer may be a single film or a stacked film that includes metallic oxide or metallic nitride. In one embodiment, the inorganic layer may include any one of SiNx, Al₂O₃, SiO₂, and TiO₂. The exposed top layer of the sealing layer 130 may be formed as an inorganic layer to prevent moisture from permeating into the OLED 70. The sealing layer 130 may include at least one sandwich structure in which at least one organic layer is inserted between at least two inorganic layers. In addition, the sealing layer 130 may include at least one sandwich structure in which at least one inorganic layer is inserted between at least two organic layers.

The sealing layer 130 may include a first inorganic layer, a first organic layer, and a second inorganic layer sequentially from the upper parts of the OLED 70 and the driving circuit unit DC. In addition, the sealing layer 130 may include a first inorganic layer, a first organic layer, a second inorganic layer, a second organic layer, and a third inorganic layer sequentially from the upper parts of the OLED 70 and the driving circuit unit DC. In addition, the sealing layer 130 may include a first inorganic layer, a first organic layer, a second inorganic layer, a second organic layer, a third inorganic layer, a third organic layer, and a fourth inorganic layer sequentially from the upper parts of the OLED 70 and the driving circuit unit DC.

A halogenated metal layer that includes LiF may further be included between the OLED 70 and the first inorganic layer. The halogenated metal layer may prevent damage to the OLED 70 and the driving circuit unit 130 when the first inorganic layer is formed by a sputtering technique or a plasma deposition technique. The first organic layer is characterized in that it is narrower than the second inorganic layer, and the second organic layer may also be narrower than the third inorganic layer. In addition, the first organic layer is characterized in that it is completely covered with the second inorganic layer, and the second organic layer may also be completely covered with the third inorganic layer.

In addition, the barrier film 120 is formed directly on the flexible substrate 110. The barrier film 120 may be formed as one or more films of various inorganic films and organic films. The barrier film 120 prevents an undesired element, such as moisture, from penetrating into the flexible substrate 110 and permeating into the OLED 70.

Because components represented in the accompanying drawings may be scaled up or down for convenience in description, it will be understood by those of ordinary skill in the art that the present invention is not constrained to the size or shape of the components represented in the accompanying drawings, and that various variations and equivalent embodiments may be made. Hence, the real protective scope of the present invention shall be determined by the technical scope of the accompanying claims, and their equivalents.

1. An organic light-emitting diode (OLED) display comprising:
a flexible substrate;
a driving circuit unit on the flexible substrate and comprising a thin film transistor (TFT);
an OLED on the flexible substrate and coupled to the driving circuit unit;
a sealing layer on the flexible substrate and covering the OLED and the driving circuit unit; and
a first protective film on the flexible substrate, wherein the first protective film comprises a photoresist material.

2. The OLED display of claim 1, wherein the first protective film comprises an epoxy-based negative tone photoresist material.

3. The OLED display of claim 2, wherein the first protective film has a thickness of 10 μm to 100 μm.

4. The OLED display of claim 2, wherein the flexible substrate comprises a plastic material.

5. The OLED display of claim 2, wherein the sealing layer comprises one or more organic layers and one or more inorganic layers that are alternately stacked.

6. The OLED display of claim 2, further comprising a barrier film directly on the flexible substrate.

7. The OLED display of claim 1, further comprising a second protective film directly on the flexible substrate, wherein the second protective film comprises a photoresist material.

8. The OLED display of claim 7, wherein the second protective film comprises an epoxy-based negative tone photoresist material.

9. The OLED display of claim 8, wherein the second protective film has a thickness of 10 μm to 100 μm.

10. The OLED display of claim 8, further comprising a barrier film directly on the second protective film.

11. A method of manufacturing an OLED display, the method comprising:
positioning a flexible substrate on a glass substrate;
forming, on the flexible substrate, a driving circuit unit comprising a thin film transistor (TFT), and an OLED coupled to the driving circuit unit;
forming, on the flexible substrate, a sealing layer on the OLED and the driving circuit unit;
separating the glass substrate from the flexible substrate; and
forming, on the flexible substrate, a first protective film comprising a photoresist material.

12. The method of claim 11, wherein the first protective film comprises an epoxy-based negative tone photoresist material.

13. The method of claim 11, wherein the first protective film is formed by a spin coating technique.

14. The method of claim 13, wherein in the spin coating technique, a thickness of the first protective film is adjusted according to a spin speed of the flexible substrate.

15. The method of claim 11, wherein the first protective film is formed by a slit coating technique.

16. The method of claim 15, wherein by the slit coating technique, a width of a slit nozzle is 650 mm to 750 mm, and a speed of the slit nozzle is 10 m/s to 20 m/s.

17. The method of claim 11, wherein the first protective film has a thickness of 10 μm to 100 μm.

18. The method of claim 11, further comprising forming a barrier film directly on the flexible substrate after positioning the flexible substrate on the glass substrate.

19. The method of claim 11, wherein the flexible substrate comprises a plastic material.

20. The method of claim 11, wherein the sealing layer comprises one or more organic layers and one or more inorganic layers that are alternately stacked.
